(19) United States
(12) Patent Application Publication
(10) Pub. No.: US 2025/0159830 A1
(43) Pub. Date: May 15, 2025

(54) ELECTRONIC MECHANISM

(71) Applicant: JVCKENWOOD Corporation, Yokohama-shi (JP)

(72) Inventors: Koichi Yoshizawa, Yokohama-shi (JP); Fumiaki Ono, Yokohama-shi (JP)

(21) Appl. No.: 19/026,636

(22) Filed: Jan. 17, 2025

Related U.S. Application Data
(63) Continuation of application No. PCT/JP2023/023265, filed on Jun. 23, 2023.

(30) Foreign Application Priority Data
Nov. 24, 2022 (JP) 2022-187302

(51) Int. Cl. H05K 5/06; G03B 17/08; H04R 1/02

(52) U.S. Cl. CPC H05K 5/069; H04R 1/021; G03B 17/08

(57) ABSTRACT

An electronic mechanism includes: an electronic component part including a microphone and a substrate; a casing accommodating the electronic component part therein; a through hole formed in the casing and placed opposite the microphone; a first groove part connected to the through hole; a second groove part of which one end part is connected to the first groove part; a third groove part that is formed in a wall part positioned adjacent to a wall part of the casing and is connected to the first groove part. The first groove part has a sloped face sloped in such a manner that cross-sectional areas increase as a distance from the through hole becomes longer.

### CROSS-REFERENCE TO RELATED APPLICATIONS

This application is a Continuation of PCT International Application No. PCT/JP2023/023265 filed on Jun. 23, 2023 which claims the benefit of priority from Japanese Patent Application No. 2022-187302 filed on Nov. 24, 2022, the entire contents of both of which are incorporated herein by reference.

### BACKGROUND OF THE INVENTION

### 1. Field of the Invention

Embodiments described herein relate generally to an electronic mechanism.

### 2. Description of the Related Art

For example, an electronic mechanism such as a drive recorder is known to be installed on a two-wheeled vehicle or the like and to have a microphone and the like accommodated therein. Known examples of recording mechanisms having a waterproof function so as to be used outdoors include the main body of a drive recorder primarily for a two-wheeled vehicle and a cameras used in such a drive recorder (see Japanese Utility Model No. 3238502, for instance). According to a technique disclosed in Japanese Utility Model No. 3238502, a ventilation hole is formed in a case part to which waterproofing has been applied, so that the ventilation hole is closed by a breathable waterproof film having both breathability and waterproof characteristics.

Electronic mechanisms to be installed on a two-wheeled vehicle and the like are required to have excellent waterproof characteristics, because the environment of use is exposed outdoors due to the installation on the two-wheeled vehicle. Thus, a test may be performed to check the waterproof characteristics thereof. According to the technique disclosed in Japanese Utility Model No. 3238502, for example, there is a possibility that the breathable waterproof film may be damaged, when a water jet is sprayed from the ventilation hole side.

### SUMMARY OF THE INVENTION

It is an object of the present invention to at least partially solve the problems in the conventional technology.

The above and other objects, features, advantages and technical and industrial significance of this invention will be better understood by reading the following detailed description of presently preferred embodiments of the invention, when considered in connection with the accompanying drawings.

An electronic mechanism apparatus according to the present disclosure comprising: an electronic component part including a microphone and a substrate; a casing accommodating the electronic component part therein; a through hole formed in a first wall part of the casing and connected to the microphone; a first groove part connected to the through hole; a second groove part of which one end part is placed opposite the first groove part; and a third groove part that is formed in a second wall part positioned adjacent to the first wall part of the casing and is connected to the first groove part, wherein the first groove part has a sloped face sloped in such a manner that cross-sectional areas increase as a distance from the through hole becomes longer toward the second groove part side.

### BRIEF DESCRIPTION OF THE DRAWINGS

FIG. 1 is a perspective view of an electronic mechanism according to a first embodiment;

FIG. 2 is a cross-sectional view of the electronic mechanism according to the first embodiment;

FIG. 3 is a partial enlarged view of FIG. 2 and illustrates a state in which a water jet is sprayed;

FIG. 4 is a partial enlarged view of FIG. 2 and illustrates a state in which a bottom face is used as an attachment face;

FIG. 5 is a partial enlarged view of FIG. 2 and illustrates a state in which a lateral face is used as an attachment face;

FIG. 6 is a partial enlarged view of an example of a conventional electronic mechanism;

FIG. 7 is a partial enlarged view of another example of a conventional electronic mechanism;

FIG. 8 is a partial enlarged view of yet another example of a conventional electronic mechanism and illustrates a state in which a bottom face is used as an attachment face;

FIG. 9 is a partial enlarged view of yet another example of a conventional electronic mechanism and illustrates a state in which a lateral face is used as an attachment face; and

FIG. 10 is a partial enlarged view of yet another example of a conventional electronic mechanism.

### DETAILED DESCRIPTION OF THE PREFERRED EMBODIMENTS

Exemplary embodiments of an electronic mechanism 1 according to the present disclosure will be explained in detail below, with reference to the accompanying drawings. The present disclosure is not limited by the embodiments described below.

### First Embodiment

### An Electronic Mechanism

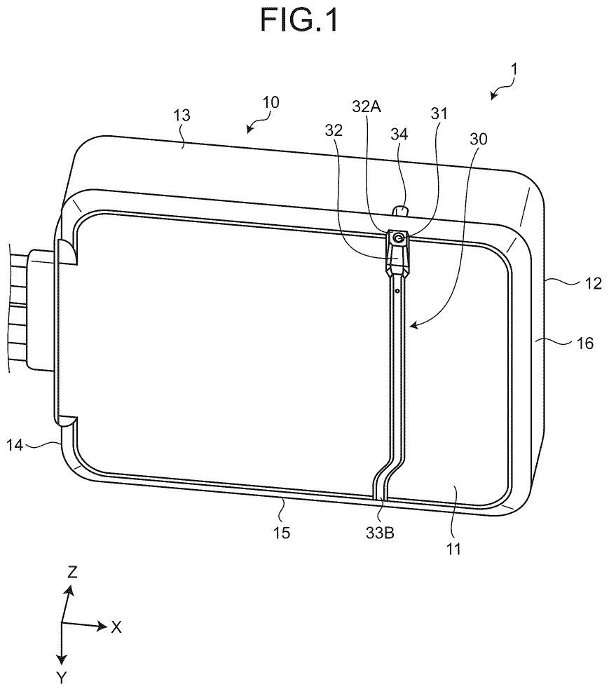

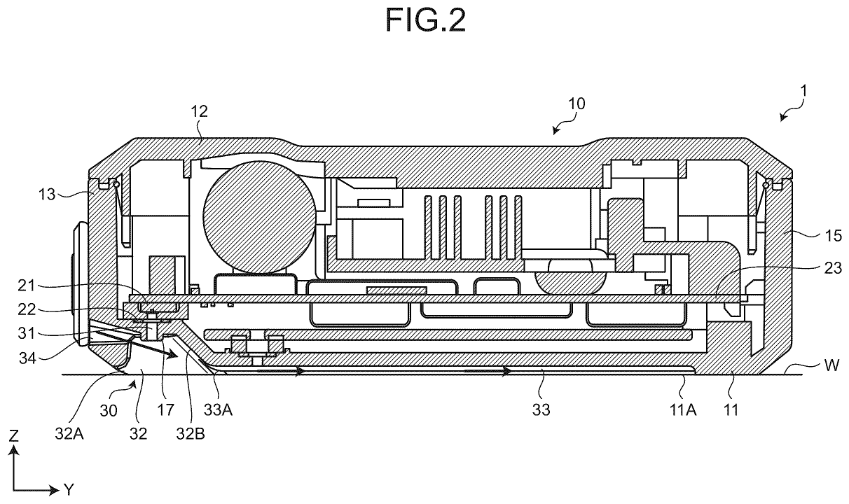

FIG. 1 is a perspective view of an electronic mechanism according to a first embodiment. FIG. 2 is a cross-sectional view of the electronic mechanism according to the first embodiment, as viewed from a wall part 12 (explained later) while being sectioned along a drainage structure 30. In the drawings, flows of water are indicated with solid arrows. The electronic mechanism 1 may be applied, for example, to a drive recorder for a two-wheeled vehicle or the like which is designed to be installed on the two-wheeled vehicle or the like and in which a camera and a casing accommodating a microphone therein are formed as separate members. In the present embodiment, an example will be explained in which the electronic mechanism 1 is a mechanism including the microphone of the drive recorder for a two-wheeled vehicle. In the following description, explanations about the camera of the drive recorder for a two-wheeled vehicle will be omitted. The electronic mechanism 1 includes a casing 10, a microphone 21 accommodated in the casing 10, a waterproof sheet 22, a substrate 23, and the drainage structure 30 formed on the casing 10.

The microphone 21 is configured to collect sounds from the outside. The microphone 21 is accommodated inside the casing 10. The microphone 21 is positioned so as to oppose a through hole 31 provided in the casing 10. The sounds collected by the microphone 21 are processed by circuitry provided on the substrate 23.

The waterproof sheet 22 is a sheet configured to prevent water from entering the microphone 21 side. The waterproof sheet 22 is structured by using a material having waterproof characteristics and breathability. The waterproof sheet 22 is positioned in an intermediate part, in terms of the axial direction, of the through hole 31. The substrate 23 is configured to control the electronic mechanism 1. The substrate 23 is accommodated inside the casing 10. The substrate 23 has installed thereon, among others, the circuitry configured to process the sounds collected by the microphone 21. The substrate 23 is positioned closer to the interior of the casing 10 relative to the microphone 21.

### The Casing

The casing 10 is formed to have the shape of a cuboidal box. The casing 10 accommodates therein electronic component parts including the microphone 21 and the substrate 23. In the present embodiment, provided inside the casing 10 are, at least, the microphone 21, the waterproof sheet 22, and the substrate 23. The casing 10 includes a wall part (a first wall part) 11, another wall part 12, yet another wall part (a second wall part) 13, yet another wall part 14, yet another wall part (a third wall part) 15, and yet another wall part 16. The exterior shape of the casing 10 is defined by the wall part 11, the wall part 12, the wall part 13, the wall part 14, the wall part 15, and the wall part 16. The wall part 11 is a bottom wall part of the casing 10. A surface 11A of the wall part 11 is an attachment face of the electronic mechanism 1. The wall part 12 is positioned so as to oppose the wall part 11. The wall part 12 is a lid part of the casing 10. The wall part 13, the wall part 14, the wall part 15, and the wall part 16 are lateral wall parts of the casing 10. The wall part 13, the wall part 14, the wall part 15, and the wall part 16 are provided so as to stand from the casing 10. The wall part 15 is provided so as to oppose the wall part 13. The wall part 16 is provided so as to oppose the wall part 14. In the present embodiment, the wall part 11, the wall part 13, the wall part 14, the wall part 15, and the wall part 16 are formed integrally.

A protrusion part 17 is a part positioned around a tip end part of the through hole 31 and protruding toward a first groove part 32 side. The protrusion part 17 is positioned closer to the viewer than the farthest part of the first groove part 32 which is positioned closest to the microphone 21 in terms of a Z-axis direction. The protrusion part 17 is integrally formed with the wall part 11 and the wall part 13.

### The Drainage Structure

The drainage structure 30 is formed in the casing 10. The drainage structure 30 includes the through hole 31, the first groove part 32, a second groove part 33, and a third groove part 34. The through hole 31 and the second groove part 33 are formed in the wall part 11. The third groove part 34 is formed in the wall part 13.

The through hole 31 is a through hole extending through to reach the microphone 21. The through hole 31 is formed in the casing 10 and is connected to the microphone 21. The through hole 31 is formed in the wall part 11. The through hole 31 is connected to the first groove part 32. The diameter of the through hole 31 is smaller than the part where the first groove part 32 is the narrowest on cross-sections thereof.

The first groove part 32 is formed in the wall part 11. An end part of the first groove part 32 positioned on the microphone 21 side in terms of the Z-axis direction is connected to the through hole 31. The first groove part 32 is formed to have a horn-like shape. As viewed in an X-axis direction, cross-sectional areas of the first groove part 32 decrease along the Z-axis direction, i.e., toward the through hole 31. The first groove part 32 has a sloped face 32B sloped in such a manner that cross-sectional areas increase as the distance from the through hole 31 becomes longer, as viewed in the X-axis direction. The first groove part 32 is exposed to the surface 11A of the wall part 11.

An end part 32A of the first groove part 32 positioned on the wall part 13 side, which is the opposite side from the through hole 31 side in terms of the Z-axis direction, is exposed to the outside, when the casing 10 is attached, for example, to an installation destination object W such as the vehicle body of a two-wheeled vehicle, while the surface 11A of the wall part 11 is used as an attachment face. The end part 32A of the first groove part 32 is capable of collecting sounds from the outside, when the casing 10 is attached to the installation destination object W while the surface 11A of the wall part 11 is used as the attachment face.

On a cross-sectional view taken in the X-axis direction, the face of the first groove part 32 positioned on the wall part 15 side in terms of a Y-axis direction will be referred to as a sloped face 32B. The sloped face 32B of the first groove part 32 is sloped so as to extend from the wall part 13 side toward the wall part 15 side, as the distance from the through hole 31 becomes longer.

The second groove part 33 is formed in the wall part 11. The second groove part 33 is connected to the first groove part 32. The second groove part 33 is formed along the Y-axis direction. One end part 33A, in terms of the Y-axis direction, of the second groove part 33 is connected to the first groove part 32. The second groove part 33 is formed so as to reach the other end part, in terms of the Y-axis direction, of the wall part 11. The second groove part 33 is formed so as to reach the wall part 15 positioned so as to oppose the wall part 13. The depth of the second groove part 33 in the Z-axis direction is shallower than that of the first groove part 32.

The other end part 33B, in terms of the Y-axis direction, of the second groove part 33 is exposed to the outside, when the casing 10 is attached to the installation destination object W while the surface 11A of the wall part 11 is used as the attachment face. The end part 33B of the second groove part 33 is able to discharge, to the outside, water that has entered the drainage structure 30, when the casing 10 is attached to the installation destination object W while the surface 11A of the wall part 11 is used as the attachment face.

The third groove part 34 is formed in the wall part 13 positioned adjacent to the wall part 11 of the casing 10. The third groove part 34 is connected to the first groove part 32. The protrusion part 17 is positioned between a connection part of the third groove part 34 connected to the first groove part 32 and the through hole 31. The third groove part 34 is exposed to the outside, when the casing 10 is attached to the installation destination object W while the surface 11A of the wall part 11 is used as the attachment face.

As viewed in the X-axis direction, the third groove part 34 has a sloped face sloped in such a manner that cross-sectional areas decrease from the top toward the bottom, as the distance from the through hole 31 becomes shorter.

### Actions of the Drainage Structure

Next, an action of the drainage structure 30 of the electronic mechanism 1 structured as described above will be explained.

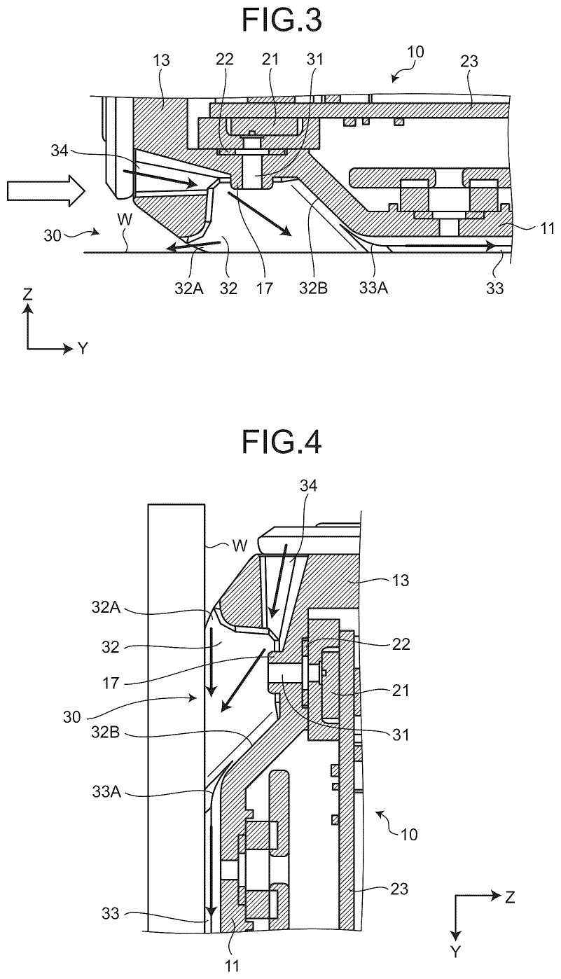

Because the electronic mechanism 1 is installed on a two-wheeled vehicle or the like, a test is performed to check waterproof characteristics thereof. An example in which a water jet is sprayed onto the electronic mechanism 1 for testing the waterproof characteristics of the electronic mechanism 1 will be explained with reference to FIG. 3. FIG. 3 is a partial enlarged view of FIG. 2 and illustrates a state in which the water jet is sprayed. In FIG. 3, in the state where the casing 10 is attached to the installation destination object W while the wall part 11 facing downward is used as an attachment face, the water jet is sprayed onto the casing 10 from the wall part 13 side, as indicated with the bold arrow. As illustrated in FIG. 3, the water jet does not directly hit the through hole 31. The water that has entered the drainage structure 30 through the third groove part 34 enters the first groove part 32. Because the third groove part 34 has the sloped face, guiding to the first groove part 32 is made easy. A part of the water that has entered the drainage structure 30 through the third groove part 34 collides with the protrusion part 17 and flows downward before entering the first groove part 32. The water that has entered the first groove part 32 and flowed downward travels along the second groove part 33 due to the waterflow and flows in the direction of the arrow, before being discharged to the outside through either the end part 33B or the end part 32A of the first groove part 32. Because the water that has entered the drainage structure 30 is discharged to the outside, the possibility that the waterproof sheet 22 may be damaged is lowered. Because the diameter of the through hole 31 is smaller than the diameter of the first groove part 32, the water that has entered the drainage structure 30 through the third groove part 34 does not easily enter the through hole 31.

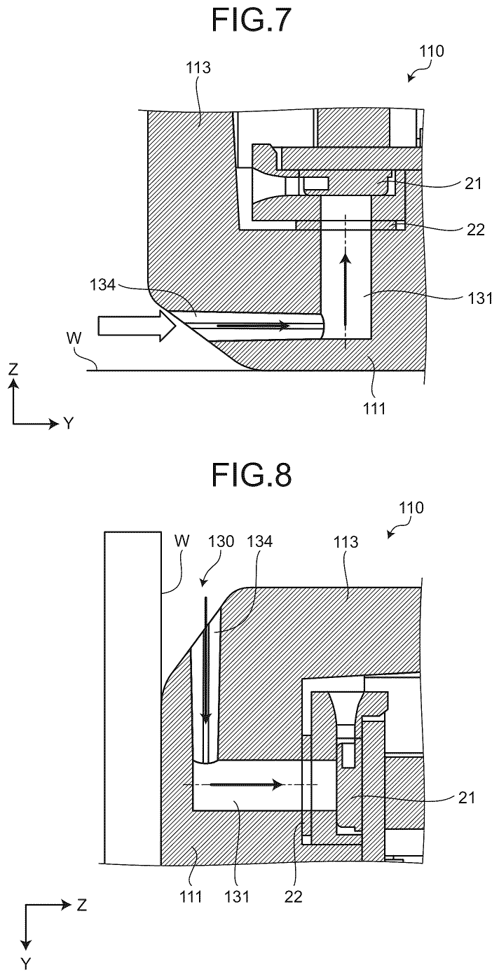

In comparison, an example in which a water jet is sprayed onto a conventional electronic mechanism will be explained, with reference to FIGS. 6 and 7. FIG. 6 is a partial enlarged view of the example of the conventional electronic mechanism. In FIG. 6, with respect to the microphone 21, a through hole 134 for a sound collection purpose is formed straight along the Y-axis direction. The through hole 134 is formed in a wall part 113 of a casing 110. In the state where the casing 110 is attached to the installation destination object W while a wall part 111 of the casing 110 facing downward is used as an attachment face, a water jet is sprayed onto the casing 110 from the wall part 113 side, as indicated with the bold arrow. The water that has entered through the third groove 134 keeps traveling and collides with the waterproof sheet 22 in a straight-on manner. Accordingly, when the water jet has strong force or when the pressure of the water has increased, there is a possibility that the waterproof sheet 22 may be damaged.

FIG. 7 is a partial enlarged view of another example of a conventional electronic mechanism. In FIG. 7, with respect to the microphone 21, a through hole 131 and the through hole 134 for a sound collection purpose are formed to be in an L-shape. The through hole 131 and the through hole 134 are connected together. With respect to the microphone 21, the through hole 131 is formed straight along the Z-axis direction. The diameter of the through hole 131 is larger than the diameter of the through hole 134. The through hole 134 is formed in the wall part 113 of the casing 110, so as to extend straight along the Y-axis direction. In the state where the casing 110 is attached to the installation destination object W while the wall part 111 of the casing 110 facing downward is used as the attachment face, a water jet is sprayed onto the casing 110 from the lateral face 13 side, as indicated with the bold arrow. The water that has entered through the third groove 134 enters the through hole 131 due to the waterflow and collides with the waterproof sheet 22. Accordingly, when the water jet has strong force or when the pressure of the water has increased, there is a possibility that the waterproof sheet 22 may be damaged.

For the conventional electronic mechanisms as illustrated in FIGS. 6 and 7, it is necessary to provide a countermeasure so that the water jet does not directly hit the waterproof sheet 22. When such a countermeasure is provided, there is a possibility that the structures of the holes and the grooves communicating with the microphone 21 for the sound collection purpose may become complicated, and costs may increase.

The drainage structure 30 of the electronic mechanism 1 will be explained, with reference to FIG. 4. FIG. 4 is a partial enlarged view of FIG. 2. Depending on the form of the two-wheeled vehicle or the like, the electronic mechanism 1 may be used while being attached in the orientation illustrated in FIG. 4. FIG. 4 illustrates a state in which the casing 10 is attached to the installation destination object W, while the wall part 11 facing a lateral side is used as an attachment face. In FIG. 4, the wall part 11 is arranged along the up-and-down direction. In FIG. 4, the wall part 13 is positioned to face upward, while the wall part 15 is positioned to face downward. Water such as rainwater enters the drainage structure 30 through the third groove part 34 and the end part 32A of the first groove part 32 positioned on the wall part 13 side, so as to enter the first groove part 32. The water that has entered through the third groove part 34 drips downward along the sloped face of the third groove part 34 and enters the first groove part 32. The water dripping from the third groove part 34 to the first groove part 32 collides with the protrusion part 17, drips downward, and enters the first groove part 32. The water that has entered the first groove part 32 drips downward, flows in the direction of the allow by following the second groove part 33, and is discharged to the outside through the end part 33B. The through hole 31 extends in a direction different from the path of the water that has entered the drainage structure 30, which makes entering the through hole 31 difficult.

In comparison, a groove structure 130 of a conventional electronic mechanism will be explained, with reference to FIG. 8. FIG. 8 is a partial enlarged view of yet another example of the conventional electronic mechanism and illustrates a state in which a bottom face is used as an attachment face. Depending on the form of a two-wheeled vehicle or the like, the conventional electronic mechanism may be used while being attached in the orientation illustrated in FIG. 8. FIG. 8 illustrates a state in which the casing 110 is attached to the installation destination object W, while the wall part 111 facing a lateral side is used as an attachment face. In FIG. 8, the wall part 111 is arranged along the up-and-down direction. In FIG. 8, the wall part 113 is positioned to face upward, while the wall part 115 (not illustrated) is positioned to face downward. The third groove 134 opens toward the top. Water such as rainwater enters the groove structure 130 through the third groove 134 and further enters the through hole 131. The water that has entered the groove structure 130 remains inside without being discharged.

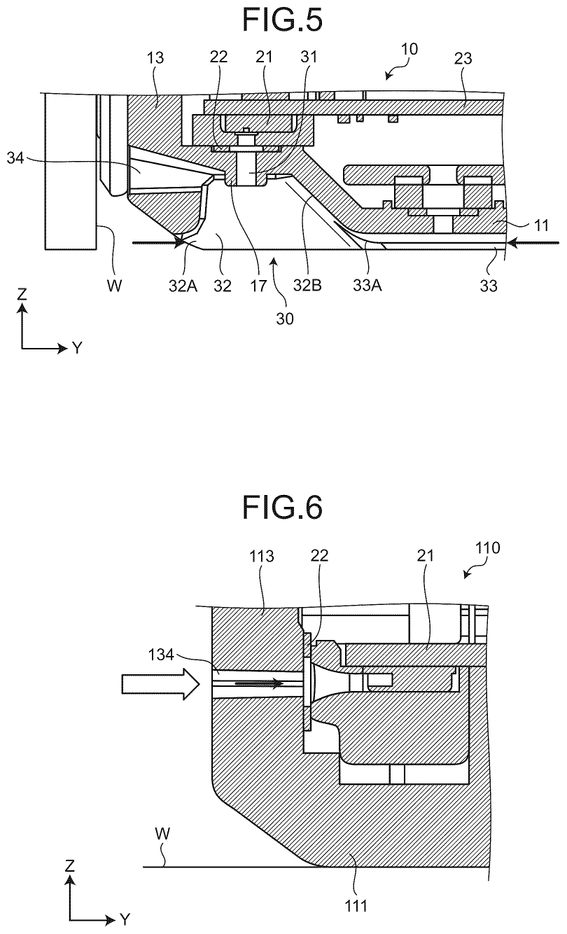

Sound collection of the electronic mechanism 1 will be explained, with reference to FIG. 5. FIG. 5 is a partial enlarged view of FIG. 2 and illustrates a state in which a lateral face is used as an attachment face. FIG. 5 illustrates the state in which the casing 10 is attached to the installation destination object W, while the wall part 13 facing a lateral side is used as an attachment face. In FIG. 5, the wall part 13 is arranged along the up-and-down direction. In FIG. 5, the wall part 12 (not illustrated) is positioned to face upward, while the wall part 11 is positioned to face downward. In this situation, the third groove part 34 is closed by the installation destination object W. In the example illustrated in FIG. 5, it is possible to collect sounds through the first groove part 32 and the second groove part 33.

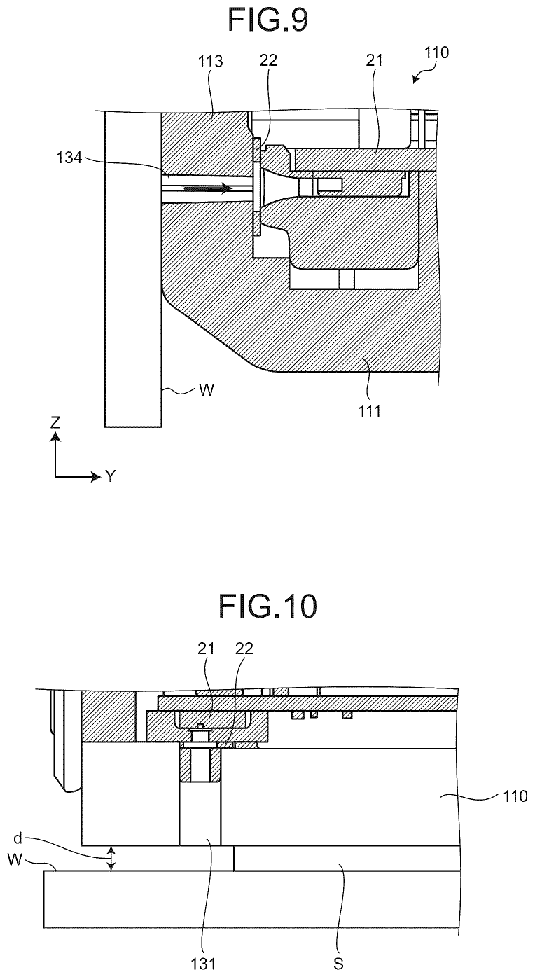

In comparison, sound collection in a conventional electronic mechanism 1 will be explained, with reference to FIGS. 9 and 10. FIG. 9 is a partial enlarged view of yet another example of the conventional electronic mechanism and illustrates a state in which a lateral face is used as an attachment face. FIG. 9 has the same configuration as that in FIG. 6. FIG. 9 illustrates the state in which the casing 110 is attached to the installation destination object W, while the wall part 113 facing a lateral side is used as the attachment face. In that situation, because the third groove 134 is closed by the installation destination object W, the sound collection is not easy. As explained herein, the conventional electronic mechanism has a constraint regarding the attachment orientation.

FIG. 10 is a partial enlarged view of yet another example of a conventional electronic mechanism. In the conventional electronic mechanism, it is necessary to provide a spacer S between the installation destination object W and the casing 110, so that the face of the casing 110 on which the through hole 131 is exposed does not get closed by the installation destination object W. As explained herein, the conventional electronic mechanism has a constraint regarding the attachment.

### Advantageous Effects

As explained above, in the present embodiment, because the third groove part 34 formed in the wall part 13 has the sloped face, it is possible to guide the water that has entered through the third groove part 34 to the first groove part 32. In the present embodiment, it is possible to guide a part of the water that has entered the drainage structure 30 through the third groove part 34, so as to collide with the protrusion part 17, to flow downward, and to enter the first groove part 32. In the present embodiment, because the water that has entered the first groove part 32 and flowed downward flows in the direction of the arrow by following the second groove part 33 due to the waterflow, it is possible to discharge the water to the outside through either the end part 33B or the end part 32A of the first groove part 32. In the present embodiment, because the water that has entered the drainage structure 30 is discharged to the outside, it is possible to lower the possibility that the waterproof sheet 22 may be damaged. As explained herein, according to the present embodiment, as illustrated in FIG. 3, during the waterproof test in which the water jet is sprayed onto the casing 10 from the wall part 113 side, in the state where the casing 10 is attached to the installation destination object W while the wall part 11 facing downward is used as the attachment face, it is possible to prevent the waterproof sheet 22 from being damaged. According to the present embodiment, it is possible to prevent the waterproof sheet from being damaged and to enhance waterproof characteristics.

In the present embodiment, it is possible to discharge, to the outside, the water that has entered the first groove part 32, through either the end part 33B of the second groove part 33 or the end part 32A of the first groove part 32. In the present embodiment, it is possible to prevent water pressure in the drainage structure 30 from increasing. In the present embodiment, because the water does not stay in the drainage structure 30, it is possible to eliminate restrictions about the orientation of the attachment face of the casing 10.

In the present embodiment, the protrusion part 17 is provided around the tip end part of the through hole 31. According to the present embodiment, it is possible to ensure that the water that has entered the drainage structure 30 through the third groove part 34 collides with the protrusion part 17 and drips downward. According to the present embodiment, it is possible to prevent the water that has entered the drainage structure 30 through the third groove part 34 from entering the through hole 31. According to the present embodiment, it is possible to enhance the waterproof characteristics of the electronic mechanism 1.

In the present embodiment, the diameter of the through hole 31 is smaller than the diameter of the first groove part 32. According to the present embodiment, it is possible to prevent the water that has entered the drainage structure 30 through the third groove part 34 from entering the through hole 31.

In the present embodiment, as illustrated in FIG. 4, when the casing 10 is attached to the installation destination object W while the wall part 11 facing the lateral side is used as the attachment face, the through hole 31 extends in the direction different from the path of the water that has entered the drainage structure 30. According to the present embodiment, it is possible to prevent the water that has entered the drainage structure 30 from entering the through hole 31. According to the present embodiment, even when the attachment is realized while the wall part 11 is arranged along the up-and-down direction, it is possible to prevent water from reaching the waterproof sheet 22.

In the present embodiment, as illustrated in FIG. 5, in the situation where the casing 10 is attached to the installation destination object W while the wall part 13 facing the lateral side is used as the attachment face, even when the third groove part 34 is closed by the installation destination object W, it is possible to collect sounds through the first groove part 32 and the second groove part 33. According to the present embodiment, it is possible to appropriately collect sounds, regardless of the orientation of the attachment face of the casing 10 and the distance from the installation destination object W. According to the present embodiment, it is possible to appropriately collect the sounds without the need to provide a spacer.

In the present embodiment, provided are the first groove part 32 and the second groove part 33 formed in the wall part 11 and the third groove part 34 formed in the wall part 13. According to the present embodiment, even when water stays in the first groove part 32 and the second groove part 33, it is possible to collect sounds through the third groove part 34. According to the present embodiment, even when water stays in the third groove part 34, it is possible to collect sounds through the first groove part 32 and the second groove part 33.

The electronic mechanism 1 of the present disclosure has thus been explained. It is, however, possible to carry out the present disclosure in other various modes different from those explained in the above embodiments.

According to the present disclosure, it is possible to enhance waterproof characteristics, while preventing a waterproof sheet from being damaged.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An electronic mechanism comprising:
an electronic component part including a microphone and a substrate;
a casing accommodating the electronic component part therein;
a through hole formed in a first wall part of the casing and placed opposite the microphone;
a first groove part connected to the through hole;
a second groove part of which one end part is connected to the first groove part; and
a third groove part that is formed in a second wall part positioned adjacent to the first wall part of the casing and is connected to the first groove part, wherein
the first groove part has a sloped face sloped in such a manner that cross-sectional areas increase as a distance from the through hole becomes longer toward the second groove part side.

2. The electronic mechanism according to claim 1, wherein the other end part of the second groove part reaches a third wall part positioned opposite the second wall part and is exposed to an outside.

3. The electronic mechanism according to claim 1, comprising: a protrusion part that is positioned around a tip end part of the through hole and protrudes to the first groove part side.

4. The electronic mechanism according to claim 3, wherein the protrusion part is positioned between a connection part of the third groove part connected to the first groove part and the through hole.

5. The electronic mechanism according to claim 1, wherein a diameter of the through hole is smaller than a part where the first groove part is narrowest on cross-sections thereof.

6. The electronic mechanism according to any one of claim 1, wherein
the first groove part is formed to have a horn-like shape, and
when the casing is attached to an installation destination object while a surface of the first wall part is used as an attachment face, an end part of the first groove part positioned opposite from the through hole side and positioned on the second wall part side is exposed to an outside.

7. The electronic mechanism according to claim 1, wherein a depth of the second groove part is shallower than that of the first groove part.

8. The electronic mechanism according to claim 1, wherein the third groove part has a sloped face sloped in such a manner that cross-sectional areas decrease as the distance from the through hole becomes shorter.

9. The electronic mechanism according to claim 1, comprising a waterproof sheet positioned in an intermediate part of the through hole.
